(19) United States
(12) Patent Application Publication
(10) Pub. No.: US 2022/0020571 A1
(43) Pub. Date: Jan. 20, 2022

(54) TEMPERATURE SENSOR AND PLASMA PROCESSING APPARATUS

(71) Applicant: Tokyo Electron Limited, Tokyo (JP)

(72) Inventors: Hiroyuki MATSUURA, Iwate (JP); Qingzhen WEN, Iwate (JP)

(21) Appl. No.: 17/370,024

(22) Filed: Jul. 8, 2021

(30) Foreign Application Priority Data
Jul. 16, 2020 (JP) 2020-122163

(51) Int. Cl. H01J 37/32; G01K 7/02; G01K 1/08; G01K 1/02

(52) U.S. Cl. CPC H01J 37/32477; G01K 7/02; H01J 2237/0266; G01K 1/026; H01J 2237/24585; G01K 1/08

(57) ABSTRACT

A temperature sensor includes: a thermocouple having a temperature measurement contact in a processing container in which a plasma processing is performed, and configured to measure a temperature inside the processing container; a protective tube configured to accommodate and protect the thermocouple; and an electromagnetic shield provided in the protective tube to cover the thermocouple.

### CROSS-REFERENCE TO RELATED APPLICATION

This application is based on and claims priority from Japanese Patent Application No. 2020-122163 filed on Jul. 16, 2020 with the Japan Patent Office, the disclosure of which is incorporated herein in its entirety by reference.

### TECHNICAL FIELD

The present disclosure relates to a temperature sensor and a plasma processing apparatus.

### BACKGROUND

In a plasma processing apparatus, a technique is known in which a noise reduction filter is connected to a compensating lead wire which is connected to a thermocouple that detects the temperature inside a reaction tube, and a shield member is incorporated to cover the compensating lead wire (see, e.g., Japanese Patent Application Laid-Open No. 2011-151081). In this technique, the noise reduction filter and the shield member are provided outside the reaction tube.

### SUMMARY

The plasma processing apparatus according to an aspect of the present disclosure is a temperature sensor that measures the temperature inside a processing container in which a plasma processing is performed. The plasma processing apparatus includes: a thermocouple having a temperature measuring contact in the processing container; a protective tube that accommodates and protects the thermocouple; and an electromagnetic shield provided in the protective tube to cover the thermocouple.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a schematic diagram illustrating an example of a plasma processing apparatus according to an embodiment.

FIG. 2 is a diagram taken along line II-II of FIG. 1.

FIG. 3 is a diagram illustrating an example of an internal temperature sensor.

FIG. 4 is a diagram taken along line IV-IV of FIG. 3.

FIG. 5 is a diagram illustrating a wire diameter and an opening of a metal mesh.

FIG. 6 is a diagram illustrating a measurement result of a shielding effect of a metal mesh.

FIG. 7 is a diagram illustrating an example of output fluctuation of a temperature sensor due to radio-frequency noise.

### DETAILED DESCRIPTION

In the following detailed description, reference is made to the accompanying drawing, which form a part thereof. The illustrative embodiments described in the detailed description, drawing, and claims are not meant to be limiting. Other embodiments may be utilized, and other changes may be made without departing from the spirit or scope of the subject matter presented here.

Hereinafter, non-limiting embodiments of the present disclosure will be described with reference to the accompanying drawings. In the accompanying drawings, the same or corresponding members or parts are denoted by the same or corresponding reference numerals, and redundant explanations thereof are omitted.

[Plasma Processing Apparatus]

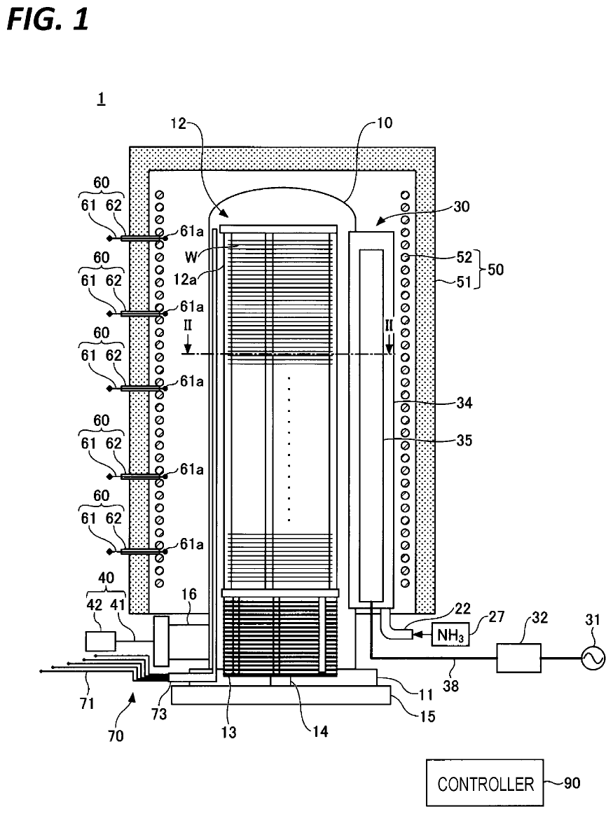

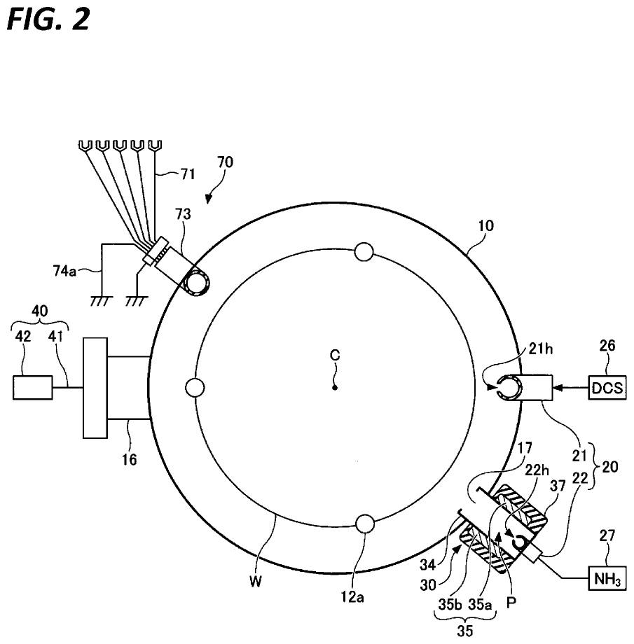

An example of a plasma processing apparatus of an embodiment will be described with reference to FIGS. 1 and 2. FIG. 1 is a schematic diagram illustrating an example of the plasma processing apparatus according to the embodiment. FIG. 2 is a diagram taken along line II-II of FIG. 1.

The plasma processing apparatus 1 includes a processing container 10, a gas supply 20, a plasma generator 30, an exhaust unit 40, a heater 50, an external temperature sensor 60, an internal temperature sensor 70, and a controller 90.

The processing container 10 has a vertical tubular shape with a ceiling and an open lower end. The entire processing container 10 is formed of, for example, quartz. A metal manifold 11 formed into a tubular shape is connected to the opening at the lower end of the processing container 10 via a sealing member (not illustrated).

The manifold 11 supports the lower end of the processing container 10, and a boat 12 on which a plurality of (e.g., 25 to 150) substrates W is placed in multiple tiers is inserted into the processing container 10 from below the manifold 11. In this way, the plurality of substrates W are accommodated in the processing container 10 substantially horizontally with an interval along the vertical direction. The substrate W is, for example, a semiconductor wafer.

The boat 12 is formed of, for example, quartz. The boat 12 has three columns 12a, and a plurality of substrates W is supported by grooves (not illustrated) formed in the columns 12a. The boat 12 is supported on a rotating shaft 14 via a heat insulating cylinder 13.

The heat insulating cylinder 13 is formed of, for example, quartz. The heat insulating cylinder 13 suppresses heat dissipation from the opening at the lower end of the processing container 10.

The rotating shaft 14 penetrates a lid 15. A magnetic fluid seal (not illustrated) is provided at the penetrating portion of the rotating shaft 14, and the rotating shaft 14 is airtightly sealed and rotatably supported. The rotating shaft 14 is attached to the tip of an arm supported by an elevating mechanism (not illustrated) such as a boat elevator, and the boat 12 and the lid 15 move up and down integrally and are inserted into and removed from the processing container 10.

The lid 15 is formed of, for example, metal. The lid 15 opens and closes the opening at the lower end of the manifold 11. A sealing member (not illustrated) for maintaining airtightness in the processing container 10 is provided between the peripheral portion of the lid 15 and the lower end of the manifold 11.

An exhaust port 16 is provided in the lower part of the side wall of the processing container 10 facing a gas nozzle 21, and the inside of the processing container 10 is evacuated through the exhaust port 16.

The gas supply 20 supplies various gases into the processing container 10. The gas supply 20 has, for example, two gas nozzles 21 and 22. However, the gas supply 20 may have another gas nozzle in addition to the two gas nozzles 21 and 22.

The gas nozzle 21 is formed of, for example, quartz, and has an L-shape that penetrates the side wall of the manifold 11 inward, is bent upward, and extends vertically. The vertical portion of the gas nozzle 21 is provided in the processing container 10. The gas nozzle 21 is connected to a dichlorosilane (DCS; SiH₂Cl₂) gas supply source 26. A plurality of gas holes 21h is formed at intervals in the vertical portion of the gas nozzle 21 over a length in the vertical direction corresponding to the wafer support range of the boat 12. Each gas hole 21h is oriented toward, for example, a center C of the processing container 10 and discharges DCS gas in the horizontal direction toward the center C of the processing container 10. However, each gas hole 21h may be oriented at an angle with respect to another direction, for example, a direction toward the center C of the processing container 10, and may be oriented toward the inner wall in the vicinity of the processing container 10.

The gas nozzle 22 is formed of, for example, quartz, and has an L-shape that is bent upward below a plasma partition wall 34, penetrates the lower portion of the plasma partition wall 34 inward, and extends vertically upward. The vertical portion of the gas nozzle 22 is provided in a plasma generation space P. The gas nozzle 22 is connected to an ammonia (NH₃) gas supply source 27. A plurality of gas holes 22h is formed at intervals in the vertical portion of the gas nozzle 22 over a length in the vertical direction corresponding to the wafer support range of the boat 12. Each gas hole 22h is oriented toward, for example, the center C of the processing container 10 and discharges ammonia gas in the horizontal direction toward the center C of the processing container 10. However, each gas hole 22h may be oriented at an angle with respect to another direction, for example, a direction toward the center C of the processing container 10.

Further, the gas nozzles 21 and 22 are also connected to a supply source (not illustrated) of the purge gas, and the purge gas is discharged into the processing container 10 from the gas holes 21h and 22h, respectively. The purge gas may be an inert gas such as argon (Ar) gas or nitrogen (N₂) gas. Further, the gas nozzle 21 may be connected to a supply source of other plasma generation gas such as hydrogen (H₂) gas or chlorine (Cl₂) gas. The gas nozzle 22 may be connected to a supply source of another raw material gas, for example, a silicon raw material gas different from the DCS gas, or a metal-containing gas.

The plasma generator 30 is formed on a part of the side wall of the processing container 10. The plasma generator 30 turns the ammonia gas supplied from the gas nozzle 22 into plasma to generate active species. The plasma generator 30 includes an RF power supply 31, a matching circuit 32, a plasma partition wall 34, a plasma electrode 35, an insulation protective cover 37, and a feeding line 38.

The RF power supply 31 is connected to the lower end of the plasma electrode 35 via a feeding line 38, and applies RF power having a predetermined frequency to the plasma electrode 35. The predetermined frequency may be, for example, 13.56 MHz, 27.12 MHz, or 68 MHz.

The matching circuit 32 is provided between the RF power supply 31 and the plasma electrode 35 in the feeding line 38. The matching circuit 32 controls the impedance on the plasma side when viewed from the RF power supply 31. The matching circuit 32 includes a coil and a capacitor (variable capacitor), and adjusts the capacitance of the variable capacitor so as to minimize the power of the reflected wave for matching. The matching circuit 32 may be, for example, an L-type matching circuit or a π-type matching circuit.

The plasma partition wall 34 is airtightly welded to the outer wall of the processing container 10. The plasma partition wall 34 is formed of, for example, quartz. The plasma partition wall 34 has a concave cross section and covers the opening 17 formed in the side wall of the processing container 10. The opening 17 is formed elongated in the vertical direction so as to cover all the substrates W supported by the boat 12 in the vertical direction. A gas nozzle 22 for discharging ammonia gas, which is a plasma generation gas, is provided in the inner space defined by the plasma partition wall 34 and communicating with the inside of the processing container 10, that is, the plasma generation space P.

The plasma electrode 35 includes a pair of electrodes 35a and 35b. The pair of electrodes 35a and 35b each have an elongated plate shape taking the vertical direction as the longitudinal direction. The pair of electrodes 35a and 35b are arranged to face each other on the outer surfaces of the walls on both sides of the plasma partition wall 34 so as to sandwich the plasma partition wall 34. A feeding line 38 is connected to the lower ends of the electrodes 35a and 35b, and RF power from the RF power supply 31 is applied via the matching circuit 32.

The insulation protective cover 37 is attached to the outside of the plasma partition wall 34 so as to cover the plasma electrode 35. The insulation protective cover 37 is formed of an insulator such as quartz.

The feeding line 38 electrically connects the RF power supply 31 and the plasma electrode 35.

The exhaust unit 40 evacuates the inside of the processing container 10 through the exhaust port 16. The exhaust unit 40 includes an exhaust pipe 41 and an exhaust device 42. The exhaust pipe 41 is connected to the exhaust port 16. The exhaust device 42 includes a pressure control valve and a vacuum pump.

The heater 50 heats the wafer W accommodated in the processing container 10. The heater 50 includes a heater chamber 51 and a heater wire 52. The heater chamber 51 has a cylindrical shape with a ceiling and is provided to surround the outer periphery of the processing container 10. The heater wire 52 is spirally provided on the inner surface of the heater chamber 51.

The external temperature sensor 60 is a temperature sensor that measures the temperature outside the processing container 10. The external temperature sensor 60 includes five sets of thermocouples 61 and five insertion tubes 62. The five sets of thermocouples 61 and the five insertion tubes 62 are provided at intervals in the vertical direction of the processing container 10.

A temperature measuring contact 61a at the tip of each thermocouple 61 is provided outside the processing container 10 and inside the heater chamber 51, and the other end thereof is pulled out of the heater chamber 51 through the insertion tube 62.

Each insertion tube 62 is provided substantially horizontally so as to penetrate the side wall of the heater chamber 51. Each insertion tube 62 is protected by inserting a thermocouple 61 inside. Each insertion tube 62 is formed of, for example, quartz.

The internal temperature sensor 70 is a temperature sensor that measures the temperature inside the processing container 10 in which a plasma processing is performed. Details of the internal temperature sensor 70 will be described later.

The controller 90 controls each part of the plasma processing apparatus 1. The controller 90 may be, for example, a computer. Further, a computer program that operates each part of the plasma processing apparatus 1 is stored in a storage medium. The storage medium may be, for example, a flexible disk, a compact disk, a hard disk, a flash memory, or a DVD.

[Internal Temperature Sensor]

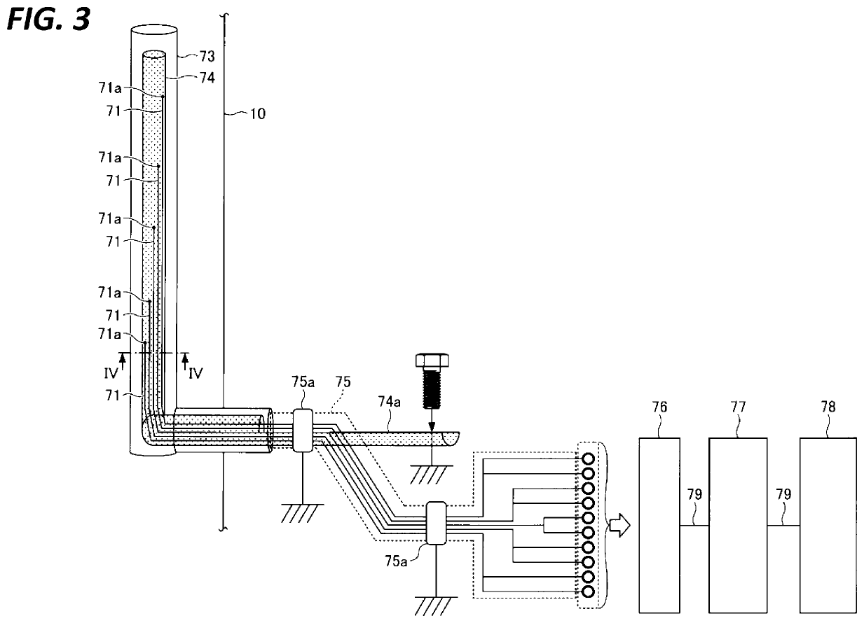

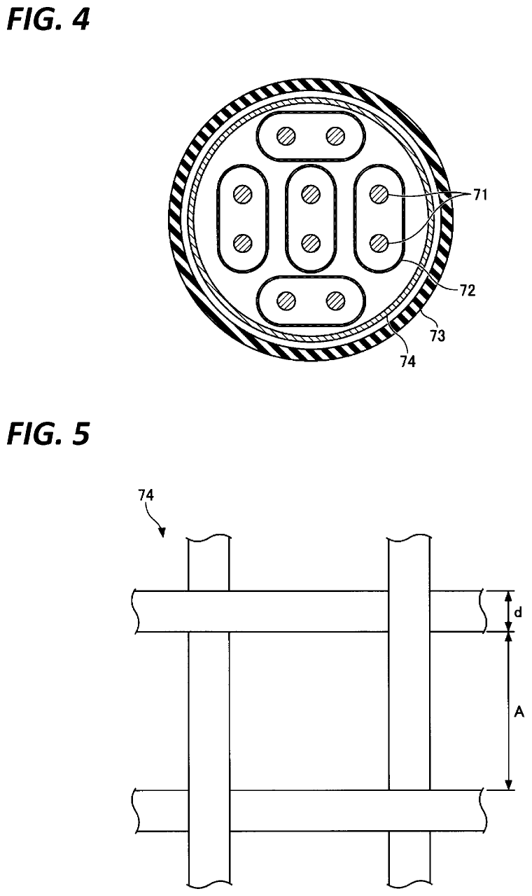

An example of the internal temperature sensor 70 will be described with reference to FIGS. 1 to 7. FIG. 3 is a diagram illustrating an example of the internal temperature sensor 70. FIG. 4 is a diagram taken along line IV-IV of FIG. 3. In FIGS. 1 and 2, for convenience of explanation, the thermocouples 71 forming a set are illustrated by one solid line.

The internal temperature sensor 70 measures the temperature inside the processing container 10. The internal temperature sensor 70 includes five sets of thermocouples 71, five insulating members 72, a protective tube 73, a metal mesh 74, a line shield 75, a relay terminal block 76, a noise filter 77, a temperature controller 78, and a compensating lead wire 79.

Each of the five sets of thermocouples 71 has a temperature measuring contact 71a at the tip provided in the processing container 10. The temperature measuring contacts 71a of the five sets of thermocouples 71 are arranged at positions having different heights in the vertical direction of the processing container 10. As a result, it is possible to measure the temperature at positions in the processing container 10 having different heights in the vertical direction. The other end of each thermocouple 71 is drawn out from the inside of the processing container 10 through the protective tube 73, and is connected to the relay terminal block 76 connected to the temperature controller 78. As a result, the temperature controller 78 may measure the temperature at the temperature measuring contact 71a of each thermocouple 71, that is, the temperature inside the processing container 10.

The five insulating members 72 are provided corresponding to the five sets of thermocouples 71, respectively. Each insulating member 72 is provided between each thermocouple 71 and the metal mesh 74 and covers each thermocouple 71. This makes it possible to suppress each thermocouple 71 from coming into direct contact with the metal mesh 74. Each insulating member 72 is formed of an insulator such as quartz.

The protective tube 73 has an L-shape that penetrates the side wall of the manifold 11 inward, is bent upward, and extends vertically. That is, one end of the protective tube 73 including the vertical portion is located inside the processing container 10, and the other end including the horizontal portion is located outside the processing container 10. The protective tube 73 has an atmosphere inside, and accommodates and protects five sets of thermocouples 71, five insulating members 72, and a metal mesh 74 inside. The temperature measuring contacts 71a of the five sets of thermocouple 71 are arranged in the vertical portion of the protective tube 73. The protective tube 73 is formed of, for example, quartz.

The metal mesh 74 is provided in the protective tube 73, and suppresses the generation of radio-frequency noise during plasma generation in the five sets of thermocouples 71. As a result, the increase in the electromotive force of the thermocouple 71 due to the radio-frequency noise is suppressed, so that the output value of the internal temperature sensor 70 may be suppressed from fluctuating with respect to the normal output value. The metal mesh 74 is preferably provided to cover each of the temperature measuring contacts 71a of at least five sets of thermocouples 71, and is provided to cover, for example, the entire five sets of thermocouples 71. The metal mesh 74 is grounded via a lead wire 74a drawn out of the processing container 10 through the other end of the protective tube 73. The lead wire 74a is screwed to, for example, a reference potential point. Since the metal mesh 74 is provided in the protective tube 73, the environment in which the metal mesh 74 is provided is in the atmosphere. Therefore, the metal mesh 74 is preferably formed of a material having oxidation resistance. Further, since the environment in which the protective tube 73 is provided reaches a high temperature (e.g., 900° C.), the environment in which the metal mesh 74 is provided is a high temperature. Therefore, the metal mesh 74 is preferably formed of a heat-resistant material. As such a material, for example, a nickel alloy may be preferably used.

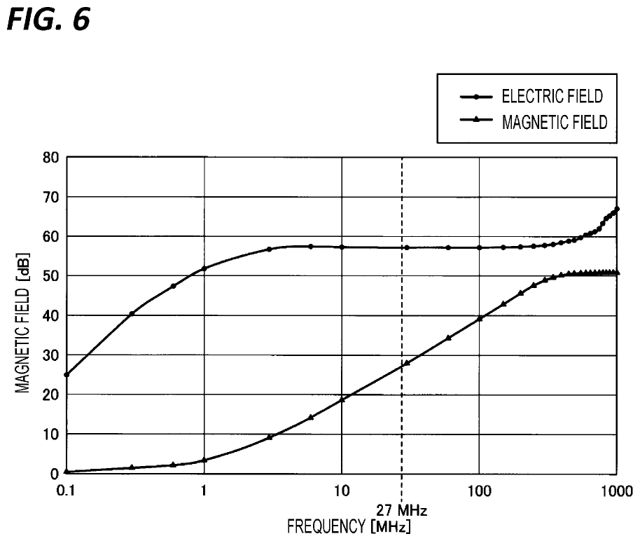

Further, the metal mesh 74 may have a shielding effect of 40 dB or more in an electric field and 20 dB or more in a magnetic field against an electromagnetic wave of 27 MHz. The shielding effect is a value measured by the KEC method developed by the KEC Kansai Electronics Industry Promotion Center. Further, the metal mesh 74 may have a mesh having high flexibility and easy processing from the viewpoint that it may be easily installed in the protective tube 73. As illustrated in FIG. 5, for example, the metal mesh 74 may have a mesh having a wire diameter d of 0.1 mm and a mesh opening A of 0.323 mm FIG. 5 is a diagram illustrating the wire diameter d and the opening A of the metal mesh 74. Further, when the shielding effect of the metal mesh 74 having a mesh having a wire diameter d of 0.1 mm and a mesh opening A of 0.323 mm was measured, a shielding effect of 40 dB or more in an electric field and 20 dB or more in a magnetic field against an electromagnetic wave of 27 MHz was found, as illustrated in FIG. 6. FIG. 6 is a diagram illustrating the measurement results of the shielding effect of the metal mesh 74, in which the horizontal axis represents the frequency [MHz] of the electromagnetic wave and the vertical axis represents the shielding effect [dB]. In FIG. 6, circles indicate the shielding effect of the electric field, and triangles indicate the shielding effect of the magnetic field.

The line shield 75 is provided outside the processing container 10 to cover the entire five sets of thermocouples 71. The line shield 75 may be, for example, a metal pipe that covers the outer portion of the processing container 10 of the five sets of thermocouples 71. The line shield 75 suppresses the generation of radio-frequency noise during plasma generation in the five sets of thermocouples 71. As a result, the increase in the electromotive force of the thermocouple 71 due to the radio-frequency noise is suppressed, so that the output value of the internal temperature sensor 70 may be suppressed from fluctuating with respect to the normal output value. The line shield 75 is grounded at one or more positions between the protective tube 73 and the relay terminal block 76, for example, via a wire clamp 75a. Further, in the example of FIG. 3, the line shield 75 is grounded via a wire clamp 75a at two positions between the protective tube 73 and the relay terminal block.

The relay terminal block 76 is provided between the five sets of thermocouples 71 and the temperature controller 78. The relay terminal block 76 connects the other ends of the five sets of thermocouples 71 to the compensating lead wire 79 connected to the temperature controller 78.

The noise filter 77 is provided between the relay terminal block 76 and the temperature controller 78 in the compensating lead wire 79. The noise filter 77 removes radio-frequency noise generated in five sets of thermocouples 71 during plasma generation. The noise filter 77 includes, for example, a ferrite core and a capacitor.

The temperature controller 78 measures the temperature at the temperature measuring contact 71a of each thermocouple 71, that is, the temperature inside the processing container 10.

The compensating lead wire 79 connects the relay terminal block 76 and the temperature controller 78.

As described above, according to the internal temperature sensor 70 of the embodiment, the metal mesh 74 is provided to cover the thermocouple 71 in the protective tube 73 provided including the inside of the processing container 10. Thus, it is possible to suppress the generation of radio-frequency noise during plasma generation in the five sets of thermocouples 71 without significantly reducing the responsiveness of the temperature measurement. As a result, the increase in the electromotive force of the thermocouple 71 due to the radio-frequency noise is suppressed, so that the output value of the internal temperature sensor 70 may be suppressed from fluctuating with respect to the normal output value.

Further, according to the internal temperature sensor 70 of the embodiment, the metal mesh 74 is added in the protective tube 73 to cover the thermocouple 71. As a result, the shapes and dimensions of the thermocouple 71, the insulating member 72, and the protective tube 73 currently in use need not be changed. Further, it is not necessary to change the design of the processing container 10. Therefore, there is no significant cost increase.

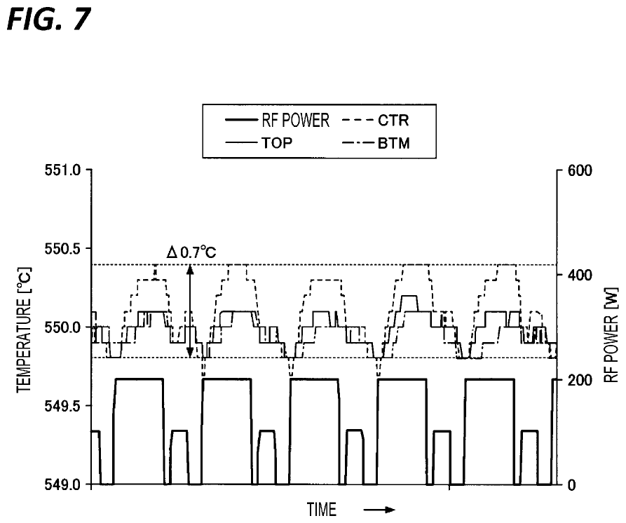

FIG. 7 is a diagram illustrating an example of the output fluctuation of the temperature sensor due to radio-frequency noise, and illustrates the output fluctuation of the internal temperature sensor when ammonia plasma is generated by RF power having a frequency of 27 MHz. In FIG. 7, the horizontal axis represents time, the first (left side) vertical axis represents temperature [° C.], and the second (right side) vertical axis represents RF power [W]. As illustrated in FIG. 7, when the RF power is switched from off to on (200 W), it may be seen that the output values (temperatures) of the three internal temperature sensors having the temperature measuring contacts at the upper portion (TOP), the central portion (CTR), and the lower portion (BTM) of the processing container 10 in the vertical direction are all increasing. In particular, it may be seen that the output value of the internal temperature sensor having the temperature measuring contact in the central portion (CTR) has a difference of 0.7° C. between the case where the RF power is on and the case where the RF power is off. It is considered that this is because the electromotive force of the thermocouple of the internal temperature sensor increases due to the radio-frequency noise during plasma generation.

In the above embodiment, the metal mesh 74 is an example of an electromagnetic shield.

In the above embodiment, descriptions have been made on the case where the processing container has a single tube structure, but the present disclosure is not limited thereto. For example, the processing container may have a double tube structure.

In the above embodiment, descriptions have been made on the case where the plasma processing apparatus is a batch type apparatus that processes a plurality of wafers at once, but the present disclosure is not limited thereto. For example, a processing apparatus may be a single-wafer processing apparatus which processes wafers one by one. In addition, the processing apparatus may be, for example, a semi-batch type apparatus which performs a process on a wafer by revolving a plurality of wafers disposed on a rotating table in a processing container by a rotating table, and sequentially passing through the region to which a first gas is supplied and the region to which a second gas is supplied.

In the above embodiment, descriptions have been made on the case where the substrate is a semiconductor wafer, but the present disclosure is not limited thereto. For example, the substrate may be a large substrate for a flat panel display (FPD), a substrate for an organic EL panel, or a substrate for a solar cell.

According to the present disclosure, the radio-frequency noise generated during plasma generation may be reduced.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A temperature sensor comprising:
a thermocouple having a temperature measurement contact in a processing container in which a plasma processing is performed, and configured to measure a temperature inside the processing container;
a protective tube configured to accommodate and protect the thermocouple; and
an electromagnetic shield provided in the protective tube to cover the thermocouple.

2. The temperature sensor according to claim 1, wherein one end of the protective tube is located inside the processing container, and a remaining end thereof is located outside the processing container.

3. The temperature sensor according to claim 2, wherein the electromagnetic shield is pulled out to an outside of the processing container through the remaining end of the protective tube and is grounded.

4. The temperature sensor according to claim 3, wherein the electromagnetic shield is provided to cover at least the temperature measurement contact.

5. The temperature sensor according to claim 4, wherein the electromagnetic shield is provided to cover the entire thermocouple.

6. The temperature sensor according to claim 5, wherein the electromagnetic shield is formed of a metal mesh.

7. The temperature sensor according to claim 6, wherein the metal mesh is formed of a nickel alloy.

8. The temperature sensor according to claim 7, wherein the electromagnetic shield has a shielding effect of 40 dB or more in an electric field and 20 dB or more in a magnetic field against an electromagnetic wave of 27 MHz.

9. The temperature sensor according to claim 8, further comprising:
an insulating member provided between the thermocouple and the electromagnetic shield.

10. The temperature sensor according to claim 9, wherein a plurality of thermocouples is accommodated in the protective tube, and
the electromagnetic shield is provided to cover all of the plurality of thermocouples.

11. The temperature sensor according to claim 1, wherein the electromagnetic field is provided to cover at least the temperature measurement contact.

12. The temperature sensor according to claim 1, wherein the electromagnetic field is provided to cover the entire thermocouple.

13. The temperature sensor according to claim 1, wherein the electromagnetic field is formed of a metal mesh.

14. The temperature sensor according to claim 1, wherein the electromagnetic shield has a shielding effect of 40 dB or more in an electric field and 20 dB or more in a magnetic field against an electromagnetic wave of 27 MHz.

15. The temperature sensor according to claim 1, further comprising:
an insulating member provided between the thermocouple and the electromagnetic shield.

16. The temperature sensor according to claim 1, wherein a plurality of thermocouples is accommodated in the protective tube, and
the electromagnetic shield is provided to cover all of the plurality of thermocouples.

17. A plasma processing apparatus comprising:
a processing container in which a plasma processing is performed; and
a temperature sensor configured to measure a temperature inside the processing container,
wherein the temperature sensor includes:
a thermocouple having a temperature measurement contact in the processing container;
a protective tube configured to accommodate and protect the thermocouple; and
an electromagnetic shield provided in the protective tube to cover the thermocouple.

18. The plasma processing apparatus according to claim 17, wherein the processing container has a tubular shape and accommodates therein a plurality of substrates in multiple tiers.
